(19) United States
(12) Patent Application Publication
(10) Pub. No.: US 2026/0003394 A1
(43) Pub. Date: Jan. 1, 2026

(54) DISPLAY STAND WITH WIRELESS CHARGING MODULE INCLUDING HEAT SINK

(71) Applicant: TORDER CO., LTD., Seoul (KR)

(72) Inventor: Jeong Jin LEE, Seoul (KR)

(21) Appl. No.: 19/237,917

(22) Filed: Jun. 13, 2025

(30) Foreign Application Priority Data
Jun. 28, 2024 (KR) 10-2024-0085039

(51) Int. Cl. G06F 1/16; F16M 13/02; G06F 1/20; G06F 1/26; H05K 7/20

(52) U.S. Cl. CPC G06F 1/1632; F16M 13/022; G06F 1/1607; G06F 1/203; G06F 1/263; H05K 7/20954

(57) ABSTRACT

An embodiment relates to a display stand to which a wireless charging module with a heat sink is applied. The display stand includes a sliding body configured in a planar form along a longitudinal direction; a display coupling portion formed at one end of the sliding body and configured to be coupled to a display mounting module on which a display is mounted; a mounting bracket configured to rotate left and right by a predetermined angle; and a coupling assembly including an upper support and a lower support formed at the other end of the sliding body to allow the stand to be mounted on an object. The coupling height is adjustable via a dual screw structure of the lower support.

### CROSS-REFERENCE TO RELATED APPLICATION

This application is based on and claims priority under 35 U.S.C. § 119 to Korean Patent Application No. 10-2024-0085039, filed on Jun. 28, 2024, in the Korean Intellectual Property Office, the disclosure of which is incorporated by reference herein in its entirety.

### BACKGROUND

### 1. Field

The present invention relates to a display stand to which a wireless charging module including a heat sink is applied, and more particularly, to a display stand configured to supply power to a display through a wireless charging module from a commercial power source or a battery, and to protect the display from heat generated during charging by including a heat sink.

### 2. Description of the Related Art

As the trend toward non-face-to-face services expands in the industry and labor costs increase, the use of tablet kiosks arranged on tables in the food service industry is on the rise. Tables placed in restaurants may be manufactured in various shapes and thicknesses. Accordingly, restaurants must purchase and install stands that are manufactured to match the respective tables.

Conventionally, most stands were designed with a fixed height to be coupled to the tabletop. These stands were typically secured by clamping onto the tabletop using screws. However, if the thickness of the tabletop exceeds the predefined height, such stands cannot be installed, and the customer must separately purchase a stand that provides a height corresponding to the thickness of the table.

In addition, in coupling a display to the stand and supplying power or performing maintenance, the wired method requires the cable to be removed each time the display is detached, causing inconvenience.

Accordingly, there is an increasing need for a display stand configured to supply power to a display via a wireless charging module from a commercial power source or a battery, and to include a heat sink to protect the display from heat generated during charging.

### SUMMARY

The present invention is intended to solve the problems of the prior art described above, and provides a display stand including a heat sink to protect the display from heat generated during charging, while supplying power to the display from a commercial power source or a battery via a wireless charging module.

However, the technical problems to be solved by the present embodiment are not limited to the aforementioned problems, and other technical challenges may exist.

To achieve the above-described technical problem, an embodiment according to a first aspect of the present disclosure provides a display stand to which a wireless charging module including a heat sink is applied. The device includes a sliding body configured in a planar form along a longitudinal direction, a display coupling part provided at one end of the sliding body and coupled to a display mounting module on which a display is mounted, a mounting bracket configured to rotate left and right by a predetermined angle, and a coupling assembly provided at the other end of the body and including an upper support and a lower support for mounting the stand to an object, wherein the coupling height is adjusted through a dual-screw structure of the lower support.

According to the present invention, wireless charging is provided by the wireless charging module, and heat generated during wireless charging can be prevented from being transferred to the display by the heat sink.

In addition, according to the present invention, the width of the fastening module can be adjusted via the dual-screw structure, allowing the mounting device to be applied to tables of various thicknesses.

Furthermore, according to the present invention, a sliding cover is installed to minimize the exposure of power or communication cables to the outside.

### BRIEF DESCRIPTION OF THE DRAWINGS

FIGS. 1 to 3 are diagrams illustrating a display stand to which a wireless charging module including a heat sink is applied according to an embodiment of the present invention.

FIGS. 4 to 10 are diagrams illustrating a coupling assembly of a display stand to which a wireless charging module including a heat sink is applied according to an embodiment of the present invention.

FIG. 11 is a diagram showing an implementation example of a display stand to which a wireless charging module including a heat sink is applied according to an embodiment of the present invention.

FIG. 12 is a diagram illustrating a battery mounting bracket of a display stand to which a wireless charging module including a heat sink is applied according to an embodiment of the present invention.

FIG. 13 is a diagram showing an implementation example in which the battery mounting bracket is applied to the display stand to which a wireless charging module including a heat sink is applied according to an embodiment of the present invention.

### DETAILED DESCRIPTION

Hereinafter, the present disclosure will be described in detail with reference to the accompanying drawings. However, the present disclosure may be implemented in various different forms and is not limited to the embodiments described herein. The drawings are merely provided to facilitate understanding of the embodiments disclosed in this specification, and the technical spirit disclosed in this specification is not limited by the drawings. All terms including technical and scientific terms used herein should be interpreted as having meanings generally understood by those of ordinary skill in the art to which the present disclosure pertains. Predetermined terms should additionally be construed as having meanings consistent with the related technical literature and the present disclosure, and unless otherwise defined, should not be interpreted as having overly ideal or excessively limited meanings.

In order to clearly describe the present invention in the drawings, parts irrelevant to the description have been omitted, and the size, shape, and form of each component shown in the drawings may be variously modified. Throughout the specification, the same or similar reference numerals are used for the same or similar parts.

Throughout the specification, when a part is described as being “connected” (i.e., coupled, contacted, or joined) to another part, it includes not only being “directly connected” but also being “indirectly connected” through another component in between. In addition, when a part is described as “including” (i.e., comprising, having, or being provided with) a component, unless otherwise specifically stated, it does not exclude the presence of other components, and may further “include” additional components.

In this specification, the term “unit” refers to a unit implemented by hardware, a unit implemented by software, or a unit implemented using both. A single unit may be implemented using two or more hardware elements, and two or more units may be implemented by a single hardware element. Meanwhile, the suffix “-unit” is not limited to software or hardware, and may be configured to reside in an addressable storage medium or to execute one or more processors. Accordingly, a “-unit” may include components such as software elements, object-oriented software components, class components, and task components, as well as processes, functions, properties, procedures, subroutines, program code segments, drivers, firmware, microcode, circuits, data, databases, data structures, tables, arrays, and variables. The functions provided within components or “-units” may be combined into a smaller number of components or “-units” or further separated into additional components or “-units”. Furthermore, the components and “-units” may be implemented to execute one or more CPUs within a device or a secure multimedia card.

The suffixes “module,” “unit,” or the like used for components in the following description are assigned and mixed for the sake of convenience in drafting the specification, and do not inherently imply different meanings or roles. Additionally, in describing the embodiments disclosed in the present specification, detailed descriptions of well-known related technologies may be omitted when deemed likely to obscure the essence of the embodiments disclosed herein.

The ordinal terms such as “first” and “second” used in the present specification are intended merely to distinguish one component from another, and do not limit the order or relationship of the components. For example, a “first” component of the present disclosure may be referred to as a “second” component, and similarly, the “second” component may also be referred to as the “first” component. The singular forms used in this specification are intended to include plural forms as well, unless the context clearly indicates otherwise.

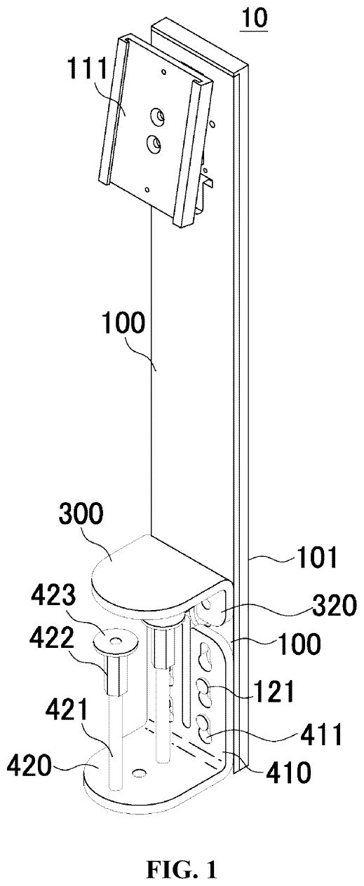

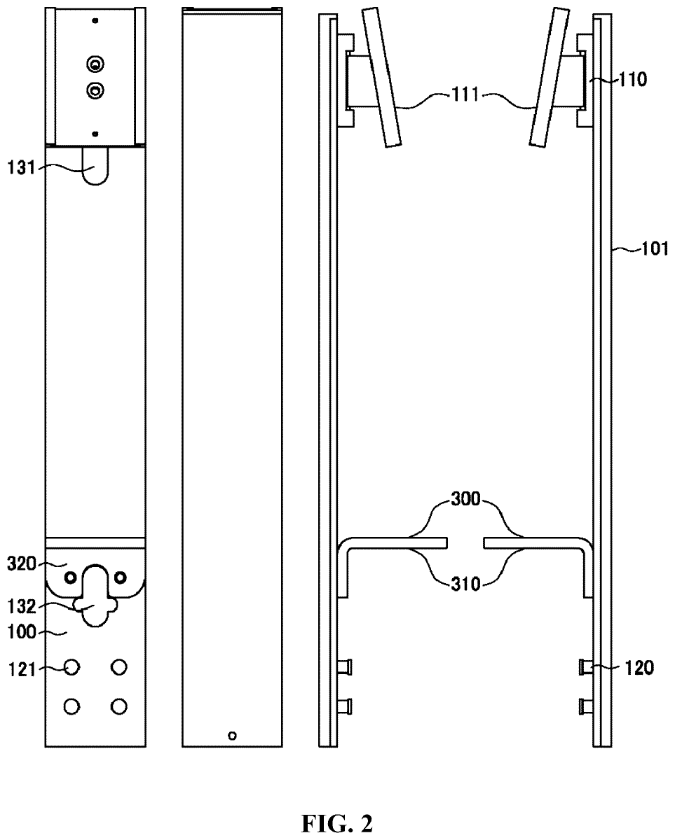

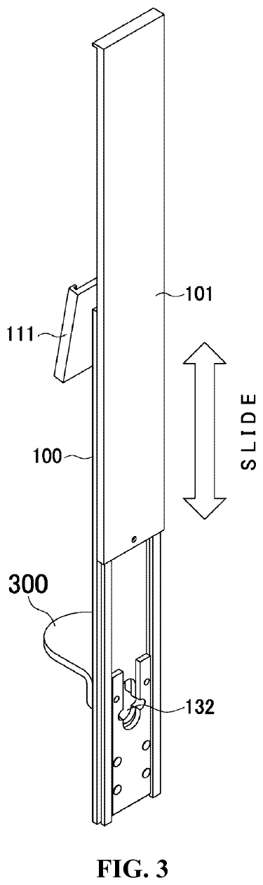

FIGS. 1 to 3 are diagrams illustrating a display stand to which a wireless charging module including a heat sink is applied, according to an embodiment of the present invention.

In the present invention, the stand may be referred to as a mounting device (10).

Referring to FIGS. 1 to 3, the mounting device (10) of the present invention includes a sliding body (100), a sliding cover (101), a mounting bracket (110), a display coupling part (111), a protrusion (120), a protrusion head (121), an upper cable inlet (131), a lower cable inlet (132), an upper support (300), and a lower support (400). Here, the upper support (300) and the lower support (400) may collectively be referred to as a coupling assembly.

The sliding body (100) may be configured in a planar form in the longitudinal direction. The sliding cover (101) may be configured to slide in the longitudinal direction along the rear surface of the sliding body (100) so as to be openable and closable. An internal space through which cables pass is formed between the sliding body (100) and the sliding cover (101), thereby preventing the cables passing through the internal space from being exposed externally.

The mounting bracket (110) includes the display coupling part (111) at one end of the sliding body (100), and may be configured to rotate to the left and right by a predetermined angle. The display coupling part (111) may be configured to couple with a display mounting module (500) on which a display is mounted. In this case, the display coupling part (111) may be coupled with the display mounting module (500) in a sliding manner. The display mounting module (500) may include a charging port for receiving power from an external source. The display mounting module (500) may include a wireless charging module. A heat sink is provided between the wireless charging module and the display, and the heat sink may prevent heat generated during wireless charging from being transmitted to the inside of the display. Here, the display may be a communication-enabled computing terminal device such as a tablet or a smartphone.

Although not shown in the drawings, the display coupling part (111) and the display mounting module (500) may be coupled in a configuration in which they respectively include a male pogo pin and a female pogo pin to allow power supply and reception. In this case, the pogo pin included in the display coupling part (111) may receive power from a battery of a battery mounting bracket or from a commercial power source, and may supply power to the pogo pin included in the display mounting module (500). The male pogo pin and the female pogo pin may include a magnet having magnetic properties, and may be connected such that the positive and negative terminals are aligned by magnetic force.

The protrusion (120) is formed on the sliding body (100), and a groove (411) formed on a lower support (400), which will be described later, may be coupled thereto. In this case, a protrusion head (121) having a larger area than the protrusion (120) may be formed at the end of the protrusion (120) to prevent separation from the coupled groove (411) when no external force is applied.

An upper cable inlet (131) and a lower cable inlet (132) are formed at the upper and lower portions, respectively, along the longitudinal direction of the sliding body (100), and a cable may pass through the upper cable inlet (131), the lower cable inlet (132), and the space between the sliding body (100) and the sliding cover to supply power to the battery or the display.

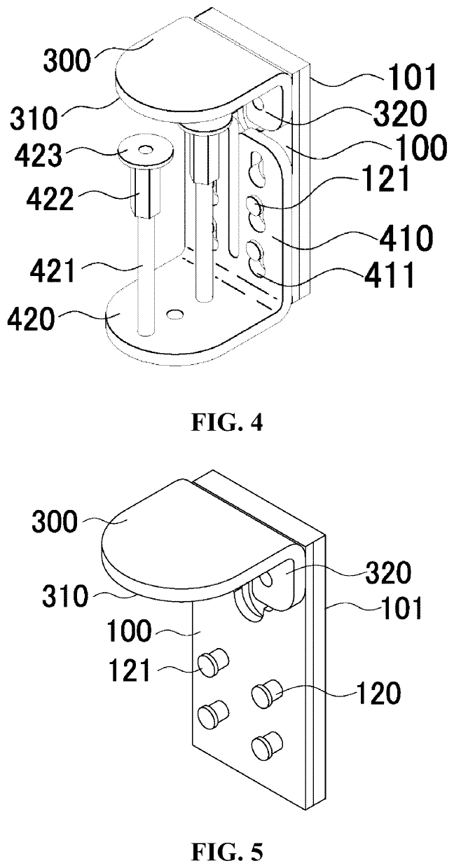

The coupling assembly including the upper support (300) and the lower support (400) may be coupled to the sliding body (100) such that the mounting device (10) can be mounted on an object. In this case, the coupling height may be adjusted based on the coupling position of the plurality of protrusions (120) formed on the sliding body (100) and the plurality of grooves (411) formed on the lower support (400). In addition, the coupling height may be adjusted using a dual-screw structure of the lower support (400). A description of the coupling assembly will be provided later with reference to FIGS. 4 to 10.

In an additional embodiment of the present invention, the sliding body (100) may further include a rotational cover that is formed with a plurality of hinges along the longitudinal direction and rotates in the direction of the hinges to open and close. This configuration allows the cover to be opened and closed in low-ceiling environments.

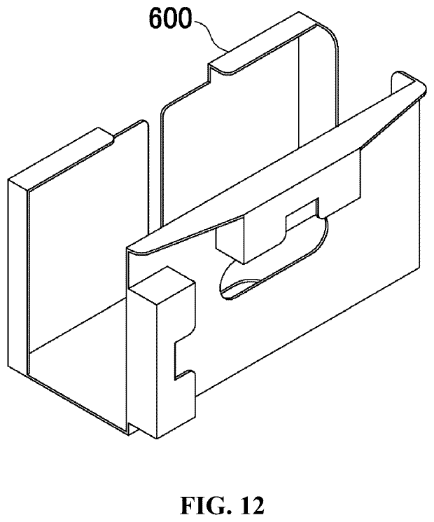

Although not shown in the drawings, the mounting device (10) may further include a card reader coupling portion and a battery mounting bracket (600). The card reader coupling portion may be formed on the sliding body (100) adjacent to the mounting bracket (110) to allow a card reader to be mounted. A description of the battery mounting bracket (600) will be provided later with reference to FIG. 12.

FIGS. 4 to 10 are views illustrating a coupling assembly of a display stander to which a wireless charging module with a heat sink is applied according to an embodiment of the present invention.

Referring to FIG. 4, the coupling assembly having a dual-screw structure according to the present invention includes a sliding body (100), an upper support (300), and a lower support (400). A plurality of protrusions (120) may be formed on the inner surface of the sliding body (100). The upper support (300) and the lower support (400) may each be composed of a plurality of surfaces. However, the configuration of the upper support (300) and the lower support (400) is not limited thereto.

The upper support (300) may include an upper horizontal support (310) formed in a plate shape in a horizontal direction to be fixed in close contact with the upper surface of an object on which the coupling assembly is mounted, and an upper vertical support (320) formed in a plate shape in a downward vertical direction from the upper horizontal support (310) such that part of it overlaps and couples with the sliding body (100).

The lower support (400) may include a lower vertical support (410) formed in a plate shape in the vertical direction and having a plurality of grooves (411) that engage with the plurality of protrusions (120), and a lower horizontal support (420) formed in a plate shape in an upward vertical direction from the lower vertical support (410), to which a plurality of first height adjustment screws (421) are coupled.

The grooves (411) may be formed such that their width narrows in a certain direction to allow the protrusions (120) to be lockingly coupled, and the first height adjustment screws (421) may be coupled with second height adjustment screws (422) configured to press the coupling assembly against the bottom surface of the object.

Referring to FIG. 5, the upper support (300) may have an “ [symbol] ” shape. However, the shape of the upper support (300) is not limited thereto.

Further, as described in FIG. 4, a first friction portion providing a certain degree of friction may be formed on the lower surface of the upper horizontal support (310), which is composed in the horizontal direction, to obtain friction. At this time, the first friction portion may be formed by directly processing the upper horizontal support (310) or by attaching a separate surface material such as non-woven fabric.

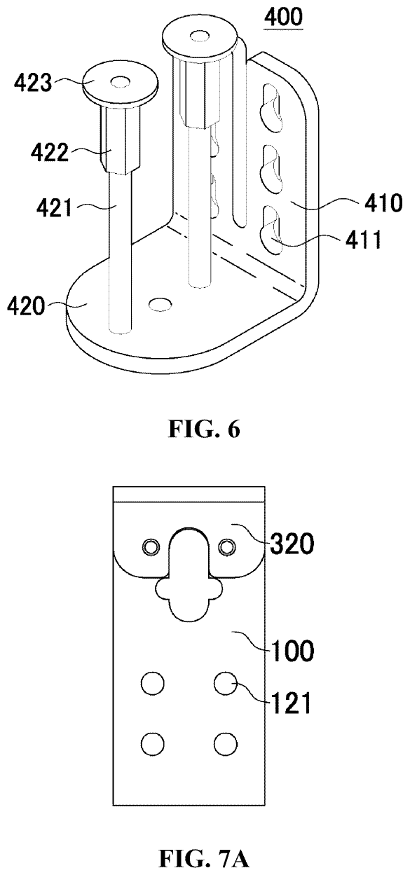

Referring to FIG. 6, the lower support (400) may have a “ [symbol] ” shape. Alternatively, although not shown in the drawings, the lower support (400) may have an “ [symbol] ” shape. However, the shape of the lower support (400) is not limited thereto.

When the lower support (400) has an “ [symbol] ” shape, grooves (411) to be engaged with the protrusions (120) of the sliding body (100) are formed on the lower vertical support (410) configured in the vertical direction of the lower support (400), and a plurality of holes into which the first height adjustment screws (421) are inserted may be formed on the lower horizontal support (420) configured in the horizontal direction of the lower support (400).

The plurality of grooves (411) may have a shape that narrows in the longitudinal direction such that the protrusions (120) are latched. The first height adjustment screws (421) may be coupled with second height adjustment screws (422), which are configured to press the mounting device (10) against the bottom surface of the object with friction. The second height adjustment screws (422), being in contact with the bottom surface of the object, may have a greater diameter than the first height adjustment screws (421) to increase friction, and may have an additional surface member such as a non-woven fabric attached thereto. In addition, the portion where the second height adjustment screws (422) contact the bottom surface of the object may be formed into a second height adjustment screw head (423) having a larger area to maximize friction.

Although not shown in the drawings, when the lower support (400) has a “ [symbol] ” shape, it may further include an extended lower vertical support (410) formed to extend in the direction of the lower vertical support (410) from the junction of the lower vertical support (410) and the lower horizontal support (420), and another groove (411) may be formed on the extended lower vertical support (410) in a direction symmetrical to the groove (411) of the lower vertical support (410) with respect to the lower horizontal support (420).

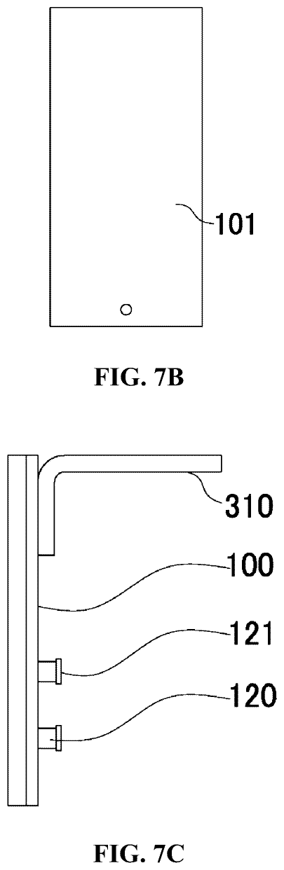

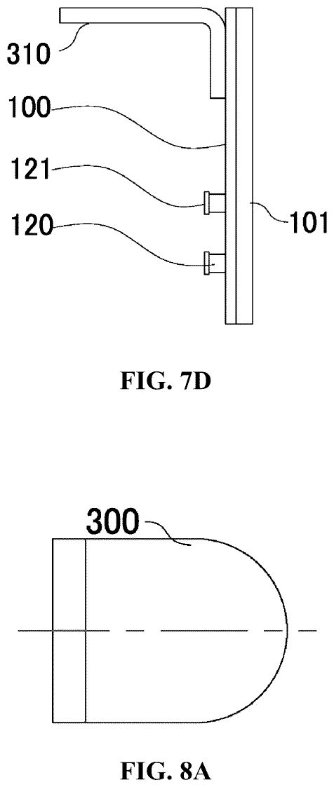

Referring to FIGS. 7A to 7D, the front view, rear view, left side view, and right side view of the upper support (300) can be identified. Referring to the front view of the upper support (300), as shown in FIG. 7A, the upper support (300) may include an upper horizontal support (310) and an upper vertical support (320) perpendicular to the upper horizontal support (310). The upper vertical support (320) may be coupled to the sliding body (100). Referring to the rear view of the upper support (300), as shown in FIG. 7B, it may be composed of the sliding cover (101). A cable or wiring may pass through the space between the sliding body (100) and the sliding cover (101) to provide video, power, and communication. Referring to the left and right side views of the upper support (300), as shown in FIGS. 7C and 7D, the protrusion (120) of the sliding body (100) may be coupled with the lower support (400), and a protrusion head (121) having a diameter larger than that of the protrusion (120) may be formed at the end to prevent detachment.

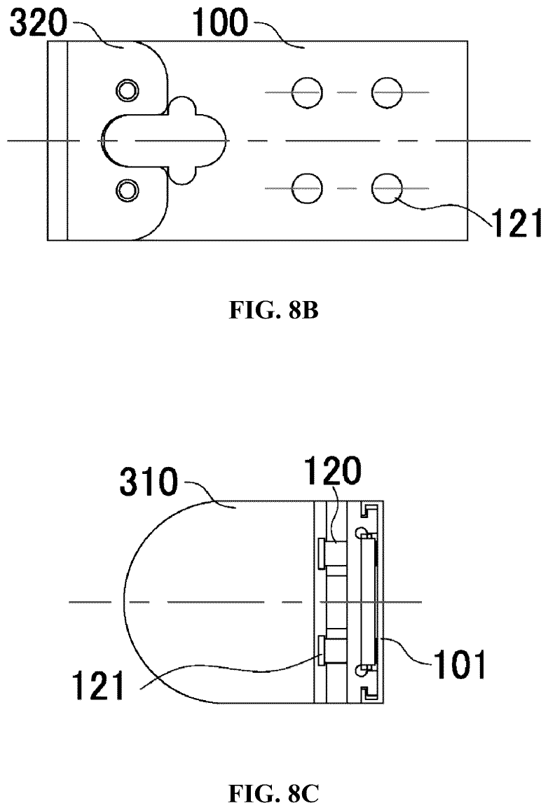

Referring to FIGS. 8A to 8C, the plan view, front view, and bottom view of the upper support (300) can be identified. Referring to the plan view of the upper support (300), as shown in FIG. 8A, the upper portion is a flat surface, and the front view is replaced with the description in FIG. 7. Referring to the bottom view of the upper support (300), as shown in FIG. 8C, the structure of the sliding cover (101) formed on the rear surface of the sliding body (100) can be identified. The sliding cover (101) has rails at the edges and may open and close by sliding along the rails of the sliding body (100) corresponding to the rails of the sliding cover (101). However, the structure of the sliding cover (101) is not limited thereto.

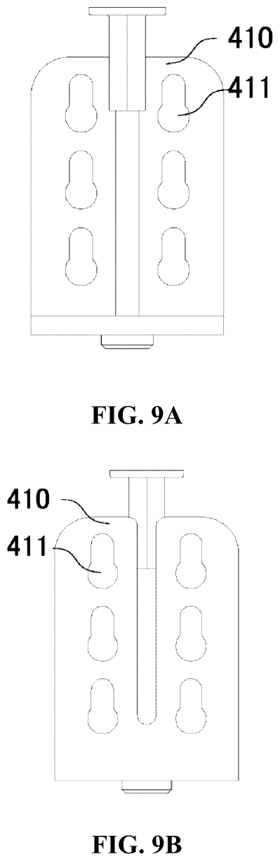

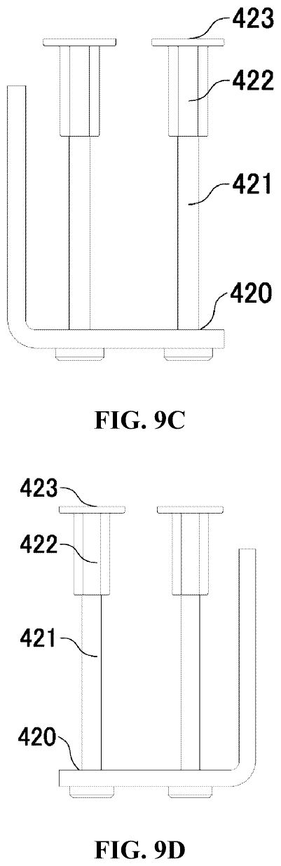

Referring to FIGS. 9A to 9D, the front view, rear view, left side view, and right side view of the lower support (400) can be identified. Referring to the front and rear views of the lower support (400), as shown in FIGS. 9A and 9B, grooves (411) to be coupled with the upper support (300) may be formed in the lower vertical support (410) extending in the longitudinal direction of the lower support (400). At this time, the grooves (411) may include pairs of grooves arranged in parallel, and the pairs of grooves may be formed in a plurality along the vertical direction of the lower vertical support (410). The protrusions (120) may include pairs of protrusions arranged in parallel, and the pairs of protrusions may be formed in a plurality along the vertical direction of the body. The first-stage height of the upper horizontal support (310) and the lower horizontal support (420) may be adjusted through the engagement of the groove pairs and protrusion pairs.

The first height adjustment screw (421) may be coupled to the lower horizontal support (420), which extends in the horizontal direction of the lower support (400). The first height adjustment screw (421) may be coupled to a second height adjustment screw (422) configured to press the coupling assembly against the bottom surface of an object with friction. Referring to the left and right side views of the lower support (400), as shown in FIGS. 9C and 9D, the first and second height adjustment screws (421, 422) may be configured as multiple units. The second height adjustment screw (422) may be formed with a larger head area, i.e., a second height adjustment screw head (423), to increase the frictional force at the portion contacting the bottom surface of the object.

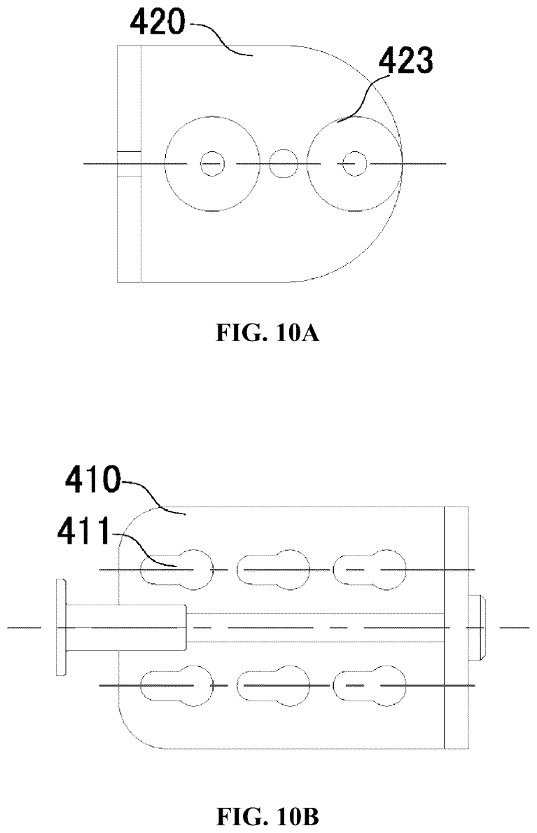

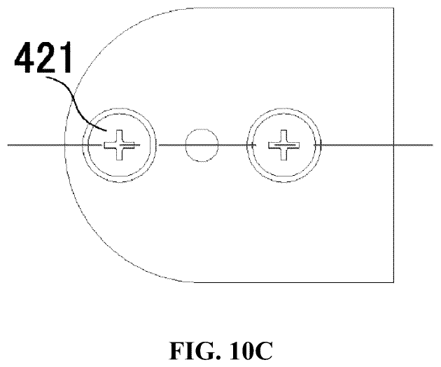

Referring to FIGS. 10A to 10C, the plan view, front view, and bottom view of the lower support (400) can be identified. Referring to the plan view in FIG. 10A, multiple second height adjustment screws (422) can be seen, and the front view is substituted with the explanation in FIG. 9. Referring to the bottom view of the lower support (400), as shown in FIG. 10C, multiple first height adjustment screws (421) can be seen.

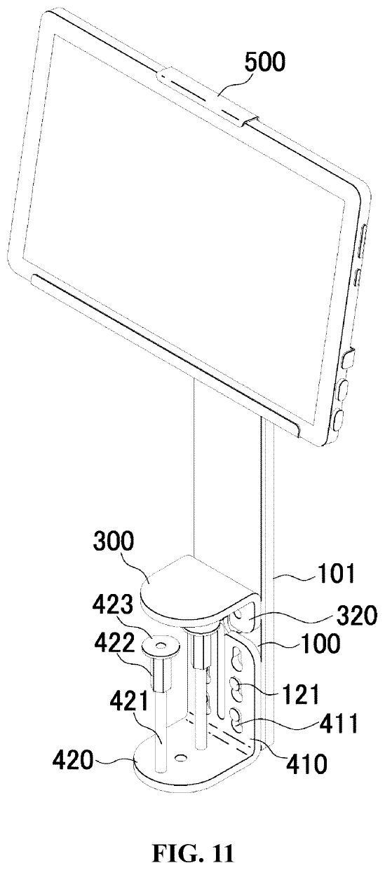

FIG. 11 is a diagram illustrating an embodiment of the display mounting device to which the wireless charging module with a heat sink according to an embodiment of the present invention is applied.

Referring to FIG. 11, the mounting device (10) having a dual-screw structure includes a display mounting module (500) coupled to the display coupling part (111), and the first-stage height of the upper horizontal support (310) and the lower horizontal support (420) can be adjusted through the engagement of the protrusions (120) of the sliding body (100) and the grooves (411) of the lower support (400). In addition, the second-stage height can be adjusted through the first height adjustment screws (421), and the third-stage height can be adjusted through the second height adjustment screws (422).

FIG. 12 is a diagram illustrating a battery holder of a display mounting device to which a wireless charging module with a heat sink according to an embodiment of the present invention is applied.

Referring to FIG. 12, the battery holder (600) includes a space where a battery can be mounted and may be configured with an open structure at the top and opposite sides. It may include a battery that supplies power to the display and the card reader.

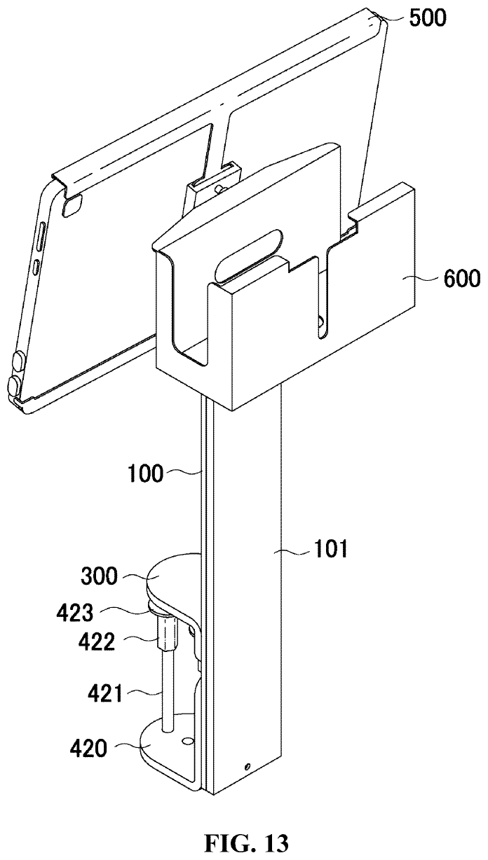

FIG. 13 is a diagram illustrating an embodiment in which a battery holder is applied to the display mounting device to which the wireless charging module with a heat sink according to an embodiment of the present invention is applied.

Referring to FIG. 13, the battery holder (600) of the present invention may be attached to the rear surface of the sliding body. Although not shown, the battery holder (600) may also be attached to the bottom surface of the lower support (400).

It will be understood by those skilled in the art that the present disclosure may be modified in various ways without departing from the spirit or essential features of the present disclosure based on the above description. Therefore, the embodiments described above should be understood as illustrative in all respects and not as limiting. The scope of the present disclosure should be defined by the claims to be described later, and all modifications or alterations derived from the meanings and scopes of the claims and their equivalents should be construed as being included in the scope of the present disclosure.

What is claimed is:

1. A display stand to which a wireless charging module with a heat sink is applied, the display stand comprising:
a sliding body configured in a planar shape along a longitudinal direction;
a mounting bracket including a display coupling portion that is coupled to a display mounting module at one end of the sliding body, and configured to rotate left and right by a preset angle; and
a coupling assembly provided at the other end of the sliding body, the coupling assembly including an upper support and a lower support, configured to mount the display stand to an object,
wherein a coupling height is adjustable through a dual-screw structure of the lower support.

2. The display stand according to claim 1,
wherein a plurality of protrusions are formed on the sliding body, and
a protrusion head having a surface area larger than that of the protrusion is formed at an end of each of the protrusions.

3. The display stand according to claim 1,
wherein a card reader coupling portion is further provided on the sliding body adjacent to the mounting bracket,
the card reader coupling portion being configured to allow a card reader to be coupled thereto.

4. The display stand according to claim 3,
wherein a battery mount is further provided on a rear surface of the sliding body,
the battery mount including a battery configured to supply power to the display and the card reader.

5. The display stand according to claim 1,
wherein the sliding body further comprises a sliding cover configured to open and close along a longitudinal direction;
an internal space is formed between the sliding body and the sliding cover through which a cable passes; and
the cable passing through the internal space is not exposed to the outside, in the display stand to which a wireless charging module with a heat sink is applied.

6. The display stand according to claim 5,
wherein a plurality of cable inlets are formed on the sliding body;
and the cable passes through an upper cable inlet formed on an upper portion of the sliding body,
a lower cable inlet formed on a lower portion of the sliding body, and the space between the sliding body and the sliding cover, to supply power to the battery or the display.

7. The display stand according to claim 1,
wherein the sliding body further comprises a plurality of hinges formed in a longitudinal direction, and a rotating cover configured to open and close in a direction of the hinges.

8. The display stand according to claim 1,
wherein the display coupling portion is coupled to the display mounting module in a sliding manner.

9. The display stand according to claim 8,
wherein the display mounting module includes a charging port configured to receive power from an external source.

10. The display stand according to claim 1,
wherein the coupling assembly is configured to adjust a coupling height through a coupling position between a plurality of protrusions formed on the sliding body and a plurality of grooves formed on the lower support.

11. The display stand according to claim 4,
wherein the battery mount is coupled to a lower end of the lower support.

12. The display stand according to claim 1,
wherein the display mounting module includes a wireless charging module,
a heat sink is provided between the display and the wireless charging module, and
the heat sink is configured to prevent heat generated during wireless charging from being transferred into the display.
